(19) United States
(12) Patent Application Publication
(10) Pub. No.: US 2024/0414910 A1
(43) Pub. Date: Dec. 12, 2024

(54) SEMICONDUCTOR DEVICE AND METHOD FOR FABRICATING THE SAME

(71) Applicant: SK hynix Inc., Gyeonggi-do (KR)

(72) Inventor: Young Gwang YOON, Gyeonggi-do (KR)

(21) Appl. No.: 18/392,737

(22) Filed: Dec. 21, 2023

(30) Foreign Application Priority Data
Jun. 12, 2023 (KR) 10-2023-0074749

(51) Int. Cl. H10B 12/00

(52) U.S. Cl. CPC H10B 12/50; H10B 12/09

(57) ABSTRACT

A semiconductor device includes: a substrate including a core region and a peripheral region; a first conductive pattern including a first stacked structure comprising a first gate dielectric layer and a first gate electrode over the substrate of the core region, and including a first high-k layer interposed at an interface between the first gate dielectric layer and the first gate electrode; and a second conductive pattern including a second stacked structure comprising a second gate dielectric layer and a second gate electrode over the substrate of the peripheral region, and including a second high-k layer interposed at an interface between the second gate dielectric layer and the second gate electrode and covering sidewalls of the second gate electrode.

### CROSS-REFERENCE TO RELATED APPLICATIONS

The present application claims priority of Korean Patent Application No. 10-2023-0074749, filed on Jun. 12, 2023, which is incorporated herein by reference in its entirety.

### BACKGROUND

### 1. Field

Various embodiments of the present invention relate to a semiconductor device, and more particularly, to a semiconductor device including a gate structure that is optimized for a peripheral region and a core region, and a method for fabricating the same.

### 2. Description of the Related Art

As semiconductor devices are integrated, there is an advantage of increasing production efficiency and reducing related costs, which makes constituent elements shrink and increases the complexity of processing and fabrication. In particular, as the dimensions of transistors decrease, the thickness of a gate oxide should be reduced to maintain performance while having a reduced gate length. To reduce gate leakage, a high-k gate dielectric layer is being used, which allows for a greater physical thickness for the dielectric layer while maintaining the same effective capacitance that is provided by a general gate oxide used for the nodes of larger technological dimensions.

Also, a method of replacing a polysilicon gate electrode with a metal gate electrode is being applied to improve the performance of a device.

### SUMMARY

Embodiments of the present invention are directed to a semiconductor device including a metal gate electrode that is optimized for a core region and a peripheral region.

In accordance with one embodiment of the present invention, a semiconductor device includes: a substrate including a core region and a peripheral region; a first conductive pattern including a first stacked structure comprising a first gate dielectric layer and a first gate electrode over the substrate of the core region, and including a first high-k layer interposed at an interface between the first gate dielectric layer and the first gate electrode; and a second conductive pattern including a second stacked structure comprising a second gate dielectric layer and a second gate electrode over the substrate of the peripheral region, and including a second high-k layer interposed at an interface between the second gate dielectric layer and the second gate electrode and covering sidewalls of the second gate electrode.

In accordance with another embodiment of the present invention, a semiconductor device includes: a substrate including a core region and a peripheral region, each region including an NMOS region and a PMOS region; a first gate structure formed over the substrate of the NMOS regions of the core region and including a first stacked structure comprising a first gate dielectric layer, a first high-k layer, and a first gate electrode; a second gate structure formed over the substrate of the NMOS regions of the peripheral region and including a second stacked structure comprising a second gate dielectric layer, a second high-k layer, and a second gate electrode; a third gate structure formed over the substrate of the PMOS regions of the core region and including a third stacked structure comprising a third gate dielectric layer, a first dipole layer, a third high-k layer, and a third gate electrode; and a fourth gate structure formed over the substrate of the PMOS regions of and the peripheral region and including a fourth stacked structure comprising a fourth gate dielectric layer, a second dipole layer, a fourth high-k layer, and a fourth gate electrode.

In accordance with another embodiment of the present invention, a semiconductor device includes: a substrate including a cell region, a core region, and a peripheral region, wherein each of the core region and the peripheral region includes an NMOS region and a PMOS region; a bit line structure formed over a substrate of the cell region; a first gate structure formed over the substrate of the NMOS regions of the core region, and including a first stacked structure of a gate dielectric layer, a high-k layer, and a gate electrode; a second gate structure formed over the substrate of the NMOS regions of the peripheral region, and including a second stacked structure of a second gate dielectric layer, a second high-k layer, and a second gate electrode; a third gate structure formed over the substrate of the PMOS regions of the core region, and including a third stacked structure of a third gate dielectric layer, a first dipole layer, a third high-k layer, and a third gate electrode; and a fourth gate structure formed over the substrate of the PMOS regions of the peripheral region, and including a fourth stacked structure of a fourth gate dielectric layer, a second dipole layer, a fourth high-k layer, and a fourth gate electrode.

In accordance with another embodiment of the present invention, a method for fabricating a semiconductor device includes: providing a substrate including a cell region, a core region and a peripheral region; forming a bit line structure in which a bit line contact, a bit line, and a bit line hard mask are stacked over the substrate of the cell region; forming a first RMG structure in which a first gate dielectric layer, a bar-shape high-k layer, and a first metal gate electrode are stacked over the substrate of the core region; and forming a second RMG structure in which a second gate dielectric layer, the U-shaped high-k layer, and a second metal gate electrode are stacked over the substrate in the peripheral region, wherein bottom surface and sidewalls of the second metal gate electrode of the second RMG structure are covered by the U-shaped high-k layer.

### BRIEF DESCRIPTION OF THE DRAWINGS

FIGS. 1A to 1C are cross-sectional views illustrating gate structures of a core region in accordance with one embodiment of the present invention.

FIGS. 2A to 2C are cross-sectional views illustrating gate structures of a peripheral region in accordance with another embodiment of the present invention.

FIG. 3 is a cross-sectional view illustrating gate structures of each region in accordance with still another embodiment of the present invention.

FIG. 4 is a cross-sectional view illustrating a semiconductor device in accordance with a further embodiment of the present invention.

FIGS. 5A to 5N are cross-sectional views illustrating a method for fabricating a semiconductor device in accordance with yet another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be complete, and will convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. In the present disclosure, the singular forms are intended to include the plural forms as well, unless the context clearly indicates otherwise.

A semiconductor memory device, particularly, a Dynamic Random Access Memory (DRAM) device, typically includes three regions. The first region may be a cell array in which memory cells are arranged in a matrix form, and the second region may be a peripheral region which is a non-repetitive circuit that stores and transfers data and drives the cell array. Hereinafter, the peripheral circuit region will be referred to as a peripheral region. The third region may be a core region which is a repetitive circuit including a sense amplifier, a decoder, and the like.

Each of the peripheral region and the core region may include an NMOS region and a PMOS region. A high voltage NMOS transistor and a low voltage NMOS transistor may be formed in the NMOS region of the peripheral region, and a high voltage PMOS transistor and a low voltage PMOS transistor may be formed in the PMOS region of the peripheral region. A high voltage NMOS transistor and a low voltage NMOS transistor may be formed in the NMOS region of the core region, and a high voltage PMOS transistor and a low voltage PMOS transistor may be formed in the PMOS region of the core region. The high voltage transistors may have a greater line width than the line width of the low voltage transistors.

The gate structures illustrated in this embodiment of the present invention may be Replacement Metal Gate (RMG) structures. A RMG structure refers to a structure obtained by forming a dummy gate pattern and a gate spacer on both sidewalls of the dummy gate pattern and replacing the dummy gate pattern with a metal gate.

In the gate structures illustrated in this embodiment of the present invention, the order that a high-k layer and a dipole layer are formed may be different according to the region where each gate structure is formed. For the sake of convenience in description of this embodiment of the present invention, the high-k layers and the dipole layers will be referred to as an HK first, an HK last, a dipole first, and a dipole last according to the order of formation. For example, an RMG structure in which a high-k layer is formed during a dummy gate formation process and remains without being removed during an RMG structure formation process may be referred to as an HK first gate structure. Also, an RMG structure in which a high-k layer is not formed during a dummy gate formation process but formed during an RMG structure formation process may be referred to as an HK last gate structure.

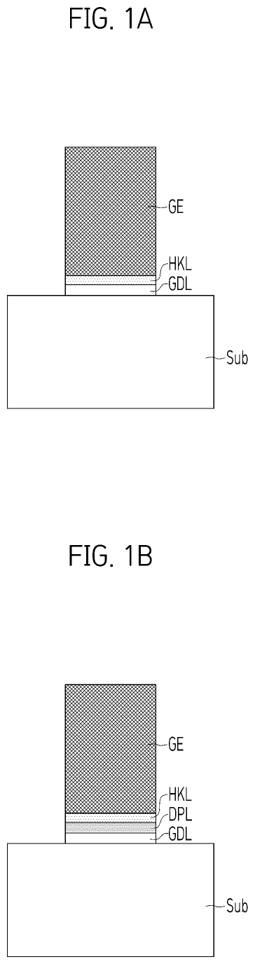

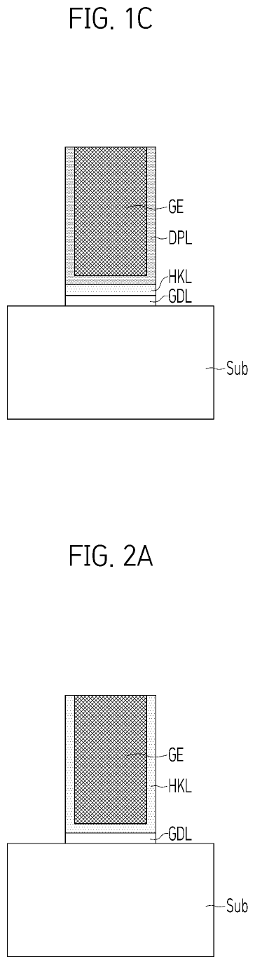

FIGS. 1A to 1C are cross-sectional views illustrating gate structures of a core region in accordance with one embodiment of the present invention. FIGS. 1A to 1C are cross-sectional views illustrating a stacked structure of gate structures, and an inter-layer dielectric layer and a gate spacer may be omitted for the sake of convenience in description.

Referring to FIGS. 1A to 1C, the gate structures of the core region may be RMG structures. The gate structures of the core region may commonly include a gate dielectric layer GDL, a high-k layer HKL, and a gate electrode GE, and a dipole layer DPL may be included or omitted according to the needs.

The gate structures in the core region may be HK first RMG structures which includes a high-k layer formed during a dummy gate pattern formation process. In other words, the high-k layer may be interposed only at the interface between the gate dielectric layer and the gate electrode and have a bar shape to maximize the control of a work function in a local region.

Each gate dielectric layer GDL illustrated in FIGS. 1A to 1C may be formed during a dummy gate pattern formation process.

Each gate electrode GE illustrated in FIGS. 1A to 1C may be formed during an RMG structure formation process. The gate dielectric layer GDL, the high-k layer HKL, and the gate electrode GE illustrated in FIGS. 1A to 1C may include the same material.

The gate dielectric layer GDL illustrated in FIGS. 1A to 1C may include, for example, silicon oxide.

The high-k layer HKL may include a high-k material having a greater dielectric constant than that of silicon oxide. For example, the high-k layer HKL may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, and combinations thereof.

The gate electrode GE may include at least one or more of a metal, a metal alloy, a conductive metal nitride, a metal silicide, a doped semiconductor material, a conductive metal oxide, and a conductive metal oxynitride. The gate electrode GE may include at least one or more of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAI), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but the concept and scope of the present invention are not limited thereto. The conductive metal oxide and the conductive metal oxynitride may be an oxidized form of the above-mentioned materials, but the concept and scope of the present invention are not limited thereto.

FIG. 1A shows an HK first gate structure that does not include a dipole layer. The HK first gate structure may include a stacked structure of a gate dielectric layer GDL and a high-k layer HKL formed during a dummy gate formation process and a gate electrode GE formed during an RMG structure formation process. The gate dielectric layer GDL and the high-k layer HKL may be sequentially stacked at the interface between the substrate Sub and the gate electrode GE. Since the gate dielectric layer GDL and the high-k layer HKL are formed through patterning, these two layers may be of a bar shape.

FIG. 1B shows a dipole first HK first gate structure. The gate structure of FIG. 1B may include a) a stacked structure of a gate dielectric layer GDL, a dipole layer DPL and a high-k layer HKL that are formed during a dummy gate formation process and b) a gate electrode GE that is formed during an RMG structure formation process. The gate dielectric layer GDL, the dipole layer GDL, and the high-k layer HKL may be sequentially stacked at the interface between the substrate Sub and the gate electrode GE. The gate dielectric layer GDL, the dipole layer DPL, and the high-k layer HKL may have a bar shape.

FIG. 1C shows a dipole last HK first gate structure. The gate structure of FIG. 1C may include a) a stacked structure of a gate dielectric layer GDL and a high-k layer HKL that are formed during a dummy gate formation process and b) a dipole layer DPL and a gate electrode GE that are formed during an RMG structure formation process. The gate dielectric layer GDL and the high-k layer HKL may be sequentially stacked at the interface between the substrate Sub and the dipole layer DPL. The gate dielectric layer GDL and the high-k layer HKL may have a bar shape. The dipole layer DPL may include a U-shaped liner. The dipole layer DPL may cover the bottom surface and side surfaces of the gate electrode GE. The top surface of the dipole layer DPL may be at the same level as the top surface of the gate electrode GE.

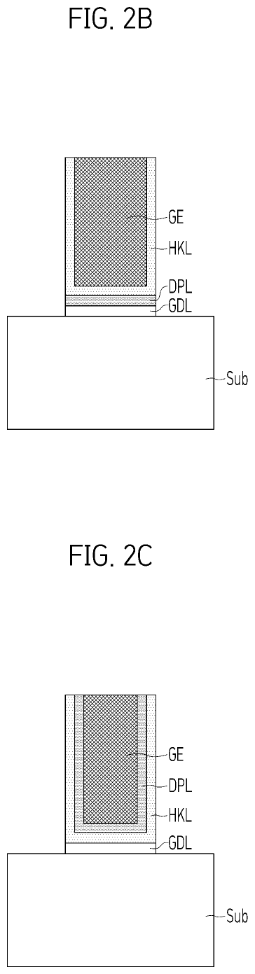

FIGS. 2A to 2C are cross-sectional views illustrating gate structures of a peripheral region in accordance with another embodiment of the present invention. FIGS. 2A to 2C are cross-sectional views illustrating a stacked structure of gate structures, and an inter-layer dielectric layer and a gate spacer may be omitted for the sake of convenience in description.

Referring to FIGS. 2A to 2C, the gate structures of the peripheral region may be RMG structures. The gate structures of the peripheral region may commonly include a gate dielectric layer GDL, a high-k layer HKL, and a gate electrode GE, and if needed, a dipole layer DPL may be included or omitted.

The gate structures of the peripheral region may be HK last RMG structures obtained by removing the high-k layer formed during the dummy gate pattern formation process and then newly applying a U-shaped high-k layer during the RMG formation process. In other words, the performance of a device may be maximized as the U-shaped high-k layer covers the bottom surface and sidewalls of the gate electrode.

The gate structures of the peripheral region may be an HK first RMG structure which applies a high-k layer of a U-shaped liner type to cover the bottom surface and sidewalls of the metal gate electrode. In other words, a high-k layer may be disposed only at the interface between the gate dielectric layer and the gate electrode and have a bar shape to maximize the control of a work function in a local region.

Each gate dielectric layer GDL illustrated in FIGS. 2A to 2C may be formed during a dummy gate pattern formation process. Each gate electrode GE illustrated in FIGS. 2A to 2C may be formed during an RMG structure formation process. Each of the gate dielectric layer GDL, the high-k layer HKL, and the gate electrode GE illustrated in FIGS. 2A to 2C may include the same material.

The gate dielectric layer GDL illustrated in FIGS. 2A to 2C may include, for example, silicon oxide.

The high-k layer HKL may include a high-k material having a higher dielectric constant than that of silicon oxide. For example, the high-k layer HKL may include at least one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, and combinations thereof.

The gate electrode GE may include at least one or more of a metal, a metal alloy, a conductive metal nitride, a metal silicide, a doped semiconductor material, a conductive metal oxide, and a conductive metal oxynitride, and combinations thereof. The gate electrode GE may include at least one or more of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAI), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but the concept and scope of the present invention are not limited thereto. The conductive metal oxide and the conductive metal oxynitride may be an oxidized form of the above-mentioned materials, but the concept and scope of the present invention are not limited thereto.

FIG. 2A may show a high-k last (HK last) gate structure that does not include a dipole. The HK last gate structure may include a) a stacked structure of a gate dielectric layer GDL that is formed during the dummy gate formation process and b) a high-k layer HKL and a gate electrode GE that are formed during the RMG structure formation process. The gate dielectric layer GDL may have a bar shape. The high-k layer HKL may include a U-shaped liner. The high-k layer HKL may cover the bottom surface and side surfaces of the gate electrode GE. The top surface of the high-k layer HKL may be at the same level as the top surface of the gate electrode GE.

FIG. 2B may show a dipole first HK last gate structure. The gate structure of FIG. 2B may include a) a stacked structure of a gate dielectric layer GDL and a dipole layer DPL that are formed during the dummy gate formation process and b) a high-k layer HKL and a gate electrode GE that are formed during the RMG structure formation process. The gate dielectric layer GDL and the dipole layer GDL may be sequentially stacked at the interface between the substrate Sub and the high-k layer HKL. The gate dielectric layer GDL and the dipole layer DPL may have a bar shape. The high-k layer HKL may include a U-shaped liner. The high-k layer HKL may cover the bottom surface and side surfaces of the gate electrode GE. The top surface of the high-k layer HKL may be at the same level as the top surface of the gate electrode GE.

FIG. 2C may show a dipole last HK last gate structure. The gate structure of FIG. 2C may include a) a stacked structure of a gate dielectric layer GDL that is formed during the dummy gate formation process and b) a high-k layer HKL, a dipole layer DPL, and a gate electrode GE that are formed during the RMG structure formation process. The gate dielectric layer GDL may have a bar shape. The high-k layer HKL and the dipole layer DPL may include a U-shaped liner. The high-k layer HKL may cover an outer wall of the dipole layer DPL. The dipole layer DPL may cover the bottom surface and side surfaces of the gate electrode GE. The top surfaces of the high-k layer HKL and the dipole layer DPL may be at the same level as the top surface of the gate electrode GE.

FIGS. 1A to 1C, which are described above, show the gate structure of the core region, and FIGS. 2A to 2C show the gate structure of the peripheral region, but the concept and scope of the present invention are not limited thereto. The gate structures illustrated in FIGS. 1A to 1C and 2A to 2C may be selectively applied to the core region or the peripheral region according to the needs. In other words, the structure may be different according to the NMOS or PMOS, and high voltage or low voltage of each region. Although it is described in the above embodiments of the present invention that the gate structures of FIGS. 1A to 1C and 2A to 2C are illustrated with the same line width, the line widths of the gate structures are not limited thereto, and the line widths may be adjusted according to the type and voltage of each region.

For example, the gate structure of FIG. 1A or 2A in which the dipole layer that deteriorates reliability is omitted may be applied to a high voltage transistor in the NMOS region.

According to another embodiment of the present invention, the dipole first gate structure of FIG. 1C or 2B may be applied to the PMOS region in order to maximize the reduction of a threshold voltage Vt.

According to yet another embodiment of the present invention, a gate structure of an HK first structure may be applied to the core region having diverse gate shapes and sizes. According to still another embodiment of the present invention, a gate structure, which is an HK last, may be applied to the NMOS region of the peripheral region to be advantageous for Tinv scaling (inversion-layer thickness scaling). According to another embodiment of the present invention, a dipole first gate structure may be applied to the PMOS region of the peripheral region to improve performance due to a decrease in the threshold voltage Vt.

The concept and scope of the present invention are not limited thereto, and an appropriate gate structure may be applied according to the gate length, purpose, and type and voltage of each region.

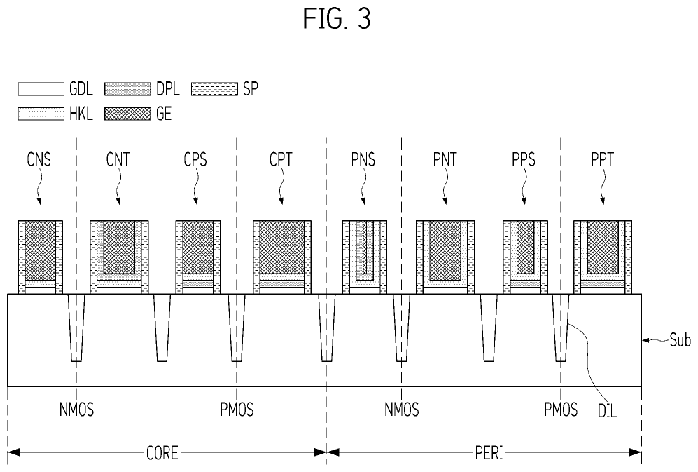

FIG. 3 is a cross-sectional view illustrating gate structures of each region in accordance with another embodiment of the present invention.

Referring to FIG. 3, according to this embodiment of the present invention, different gate structures may be applied for each type and voltage of the core region CORE and the peripheral region PERI. In particular, a HK first gate structure may be applied to the core region CORE which needs to adjust a work function of a local region. Also, the HK last gate structure may be applied to the peripheral region PERI which requires to maximize performance.

According to this embodiment of the present invention, an isolation layer DIL defining an active region may be formed, while dividing a substrate Sub into a core region CORE and a peripheral region PERI, dividing each of the core region CORE and the peripheral region PERI into an NMOS region and a PMOS region, and dividing each of the NMOS region and PMOS region into a high voltage transistor region and a low voltage transistor region at the same time.

First, the core region CORE may be divided into an NMOS region and a PMOS region. Also, the NMOS region of the core region CORE may be divided into a low voltage transistor region and a high voltage transistor region.

A gate structure having a smaller line width than that of the high voltage transistor region may be applied to the low voltage transistor region of the NMOS region of the core region CORE. The gate structure CNS formed in the low voltage transistor region of the NMOS region of the core region CORE may be an HK first gate structure that does not include a dipole layer, which is illustrated in FIG. 1A, to improve the reliability of a device. The gate structure CNT formed in the high voltage transistor region of the NMOS region of the core region CORE may be a dipole last HK first gate structure shown in FIG. 1C to reduce the threshold voltage.

According to another embodiment of the present invention, the dipole last HK first gate structure shown in FIG. 1C may be applied to the low voltage transistor region of the NMOS region of the core region CORE to reduce the threshold voltage. According to yet another embodiment of the present invention, the HK first gate structure that does not include a dipole layer shown in FIG. 1A may be applied to the high voltage transistor region of the NMOS region of the core region CORE to improve the reliability of a device.

The PMOS region of the core region CORE may be divided into a low voltage transistor region and a high voltage transistor region.

A gate structure having a smaller line width than that of the high voltage transistor region may be applied to the low voltage transistor region of the PMOS region of the core region CORE. The dipole first HK first gate structure shown in FIG. 1B may be applied to the gate structure CPS which is formed in the low voltage transistor region of the PMOS region of the core region CORE to reduce the threshold voltage Vt. The dipole first HK first gate structure shown in FIG. 1B may be applied to the gate structure CPT which is formed in the high voltage transistor region of the PMOS region of the core region CORE to reduce the threshold voltage Vt. In other words, the same gate structure may be applied to the PMOS region of the core region CORE, regardless of the gate line width, but the concept and scope of the present invention are not limited thereto.

The peripheral region PERI may be divided into an NMOS region and a PMOS region. Also, the NMOS region of the peripheral region PERI may be divided into a low voltage transistor region and a high voltage transistor region.

A gate structure having a smaller line width than that of the high voltage transistor region may be applied to the low voltage transistor region of the NMOS region of the peripheral region PERI. The dipole last HK last gate structure shown in FIG. 2C may be applied to the gate structure PNS which is formed in the low voltage transistor region of the NMOS region of the peripheral region PERI to reduce the threshold voltage. The HK last gate structure that does not include a dipole layer shown in FIG. 2A may be applied to the gate structure PNT which is formed in the high voltage transistor region of the NMOS region of the peripheral region PERI to improve the reliability of a device.

The PMOS region of the peripheral region PERI may be divided into a low voltage transistor region and a high voltage transistor region.

A gate structure having a smaller line width than that of the high voltage transistor region may be applied to the low voltage transistor region of the PMOS region of the peripheral region PERI. The dipole first HK last gate structure shown in FIG. 2B may be applied to the gate structure PPS which is formed in the low voltage transistor region of the PMOS region of the peripheral region PERI to reduce the threshold voltage. The dipole first HK last gate structure shown in FIG. 2B may be applied to the gate structure PPT which is formed in the high voltage transistor region of the PMOS region of the peripheral region PERI to reduce the threshold voltage. In other words, the same gate structure may be applied to the PMOS region of the peripheral region PERI, regardless of the gate line width, but the concept and scope of the present invention are not limited thereto.

As described above, the present embodiment of the present invention may apply a gate structure which is optimized according to the type, gate line width, and voltage of each region, but the concept and scope of the present invention are not limited thereto. The gate structures shown in FIGS. 1A to 1C and 2A to 2C may be selectively adopted and applied to each region according to the needs.

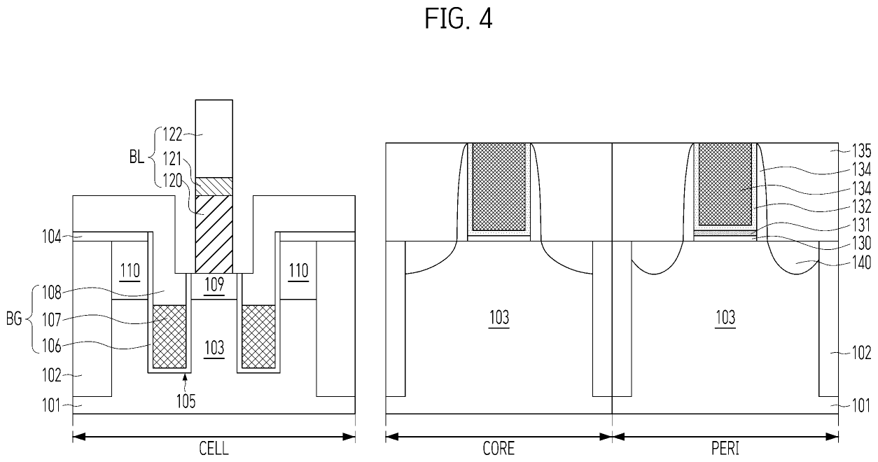

FIG. 4 is a cross-sectional view illustrating a semiconductor device in accordance with another embodiment of the present invention.

Referring to FIG. 4, the substrate 101 may include a cell region CELL, a core region CORE, and a peripheral region PERI.

The substrate 101 may be a material suitable for semiconductor processing. The substrate 101 may include a semiconductor substrate. The substrate 101 may be formed of a silicon-containing material. The substrate 101 may include for example one or more of silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include another semiconductor material, such as for example germanium. The substrate 101 may include a III/V-group semiconductor substrate, for example, a compound semiconductor substrate, such as GaAs. The substrate 101 may include a Silicon-On-Insulator (SOI) substrate.

The substrate 101 may define an active region 103 while being divided into the cell region CELL, the core region CORE, and the peripheral region PERI by the isolation layer 102. The isolation layer 102 may be a shallow trench isolation region (STI) that is formed by a trench etching process. The isolation layer 102 may be formed by filling a shallow trench, for example, an isolation trench 102T, with a dielectric material. The isolation layer 102 may include silicon oxide, silicon nitride, or a combination thereof.

The cell region CELL may include a buried gate structure BG and a bit line structure BL.

The buried gate structure BG may be formed in the substrate 101. The buried gate structure BG may be buried in a gate trench 105 using a hard mask layer 104 formed over the substrate 101 as an etch barrier. The bottom surface of the gate trench 105 may be disposed at a higher level than the bottom surface of the isolation layer 102.

The buried gate structure BG may include a buried gate dielectric layer 106 covering the bottom surface and the inner sidewall of the gate trench 105, and a buried gate electrode 107 and a capping layer 108 that are sequentially stacked to fill the gate trench 105 over the buried gate dielectric layer 106.

The buried gate dielectric layer 106 may include one or more of silicon oxide, silicon nitride, silicon oxynitride, a high-k material, or a combination thereof.

The buried gate electrode 107 may have a single-layer structure or a multi-layer structure. The buried gate electrode 107 may include a semiconductor material or a metal-based material. The buried gate electrode 107 may include a metal material or a metal nitride. For example, the buried gate electrode 107 may include titanium nitride (TiN). According to another embodiment of the present invention, the buried gate electrode 107 may include one or more selected from the group including titanium nitride (TiN), molybdenum (Mo), tantalum nitride (TaN), lanthanum (La), hafnium (Hf), tantalum (Ta), aluminum (Al), aluminum oxide (Al₂O₃), titanium silicon nitride (TiSiN), and tantalum silicon nitride (TaSiN), and combinations thereof, but the concept and scope of the present invention are not limited thereto.

The capping layer 108 may fill the upper portion of the gate trench 105 over the buried gate electrode 107. The capping layer 108 may extend over the hard mask layer 104 of the cell region CELL. The capping layer 108 may include a dielectric material. For example, the capping layer 108 may include one or more of silicon nitride, silicon oxide, silicon oxynitride, or a combination thereof.

A first source/drain region 109 and a second source/drain region 110 may be formed in the active region 103 of the cell region CELL. The first source/drain region 109 and the second source/drain region 110 may be a region that is doped with a conductive dopant. For example, the conductive dopant may include one or more of phosphorus (P), arsenic (As), antimony (Sb), or boron (B). The first source/drain region 109 and the second source/drain region 110 may be doped with dopants of the same conductivity type. The first source/drain region 109 and the second source/drain region 110 may be disposed in the active region 103 on both sides of the gate trench 105. The bottom surfaces of the first source/drain region 109 and the second source/drain region 110 may be disposed at a predetermined depth from the top surface of the active region 103. The bottom surfaces of the first source/drain region 109 and the second source/drain region 110 may be at a higher level than the bottom surface of the gate trench 105.

The bit line structure BL may be coupled to the first source/drain region 109. The second source/drain region 110 may be coupled to a memory device through a storage node contact.

The bit line structure BL may include a stacked structure of a bit line contact 120, a bit line 121, and a bit line hard mask 122. The bottom surface of the bit line contact 120 may be disposed at a lower level than the top surface of the substrate 101. The bit line contact 120 may be formed of polysilicon or a metal material. The bit line 122 may include a metal material. The bit line hard mask 123 may include a dielectric material.

Each of the core region CORE and the peripheral region PERI may be divided into an NMOS region and a PMOS region, as illustrated in FIG. 3. The NMOS region of the core region CORE may be divided into a low voltage transistor region and a high voltage transistor region. The PMOS region of the core region CORE may be divided into a low voltage transistor region and a high voltage transistor region. Each of the NMOS region and the PMOS region of the peripheral region PERI may also be divided into a low voltage transistor region and a high voltage transistor region.

The core region CORE and the peripheral region PERI may include a gate structure that is optimized according to the type (e.g., NMOS region and PMOS region) or line width (e.g., high voltage and low voltage) of each region. The core region CORE and the peripheral region PERI may include an RMG structure. The gate structures of the core region CORE and the peripheral region PERI may include a stacked structure of a gate dielectric layer 130, a high-k layer 132, and a gate electrode 133, individually. It may further include a dipole layer 131 if necessary, but the concept and scope of the present invention are not limited thereto. One or more of the gate structures illustrated in FIGS. 1A to 1C and 2A to 2C may be applied to the gate structures of the core region CORE and the peripheral region PERI, if necessary. Gate spacers 134 may be formed on both sidewalls of each gate structure. An inter-layer dielectric layer 135 may be buried between the gate structures.

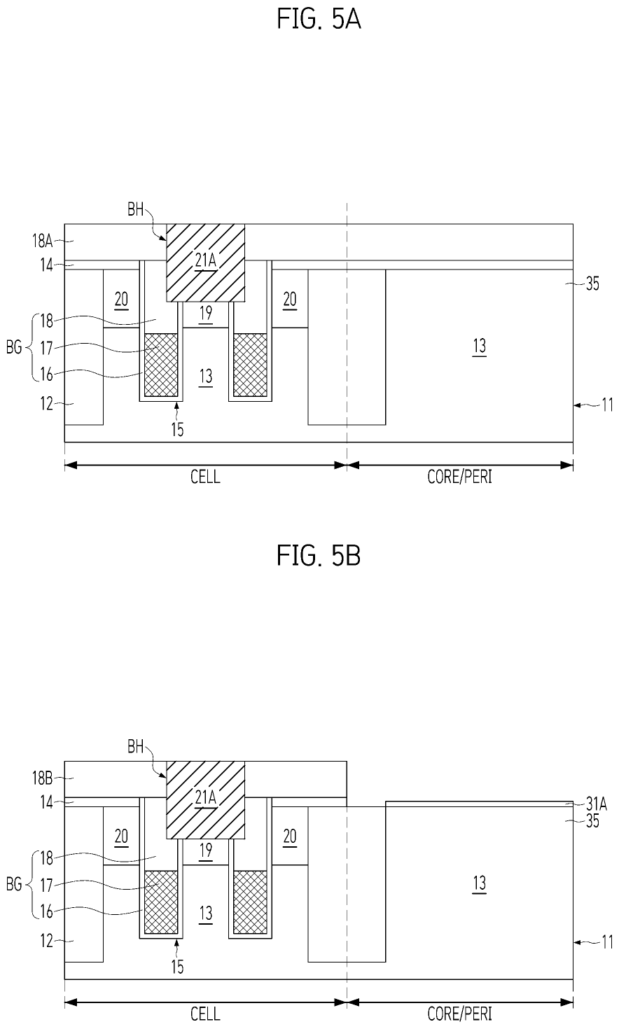

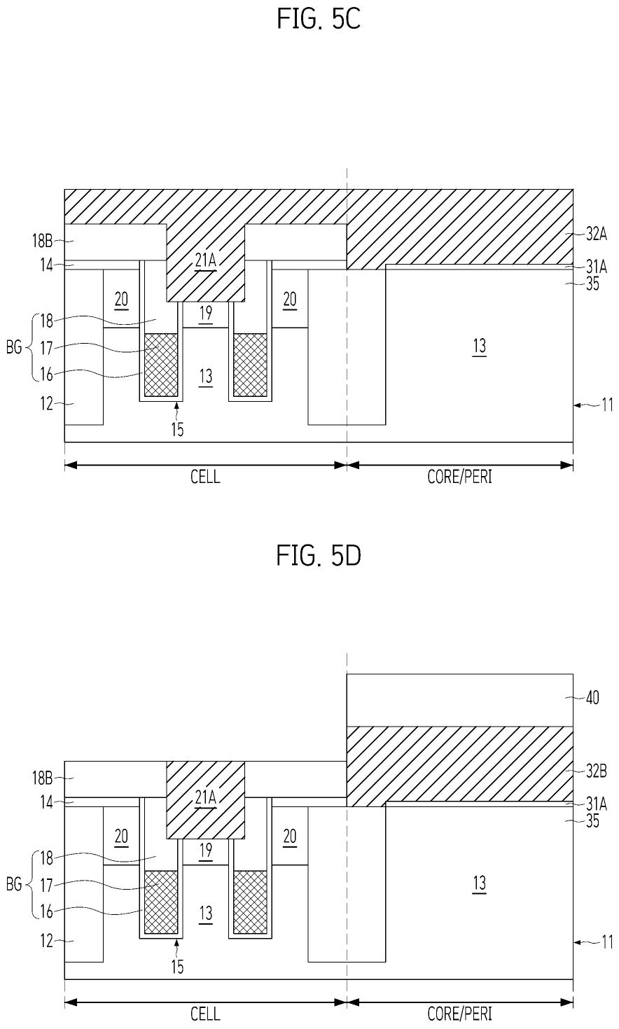

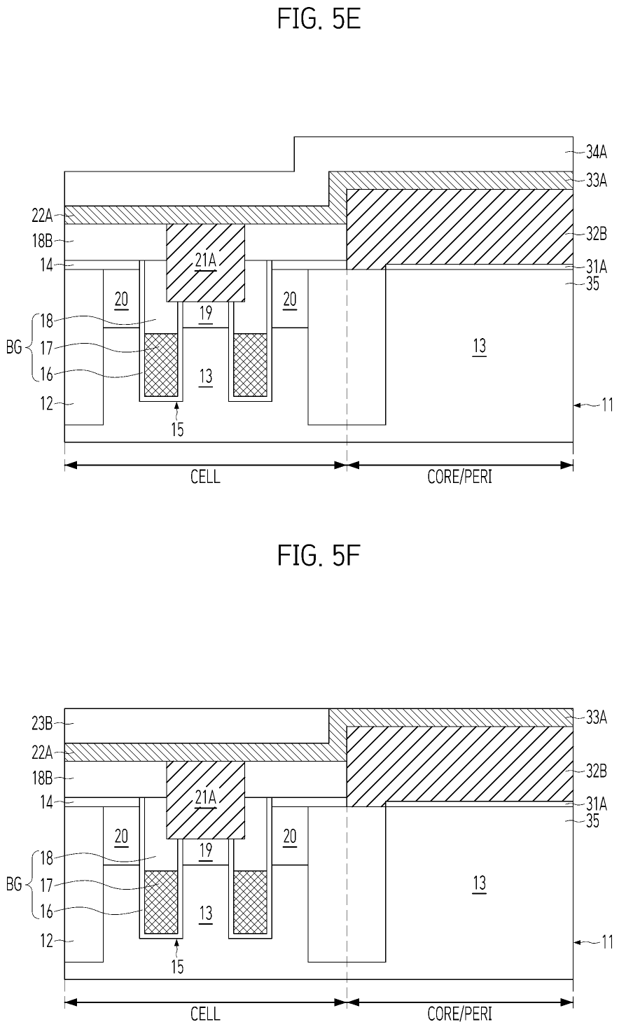

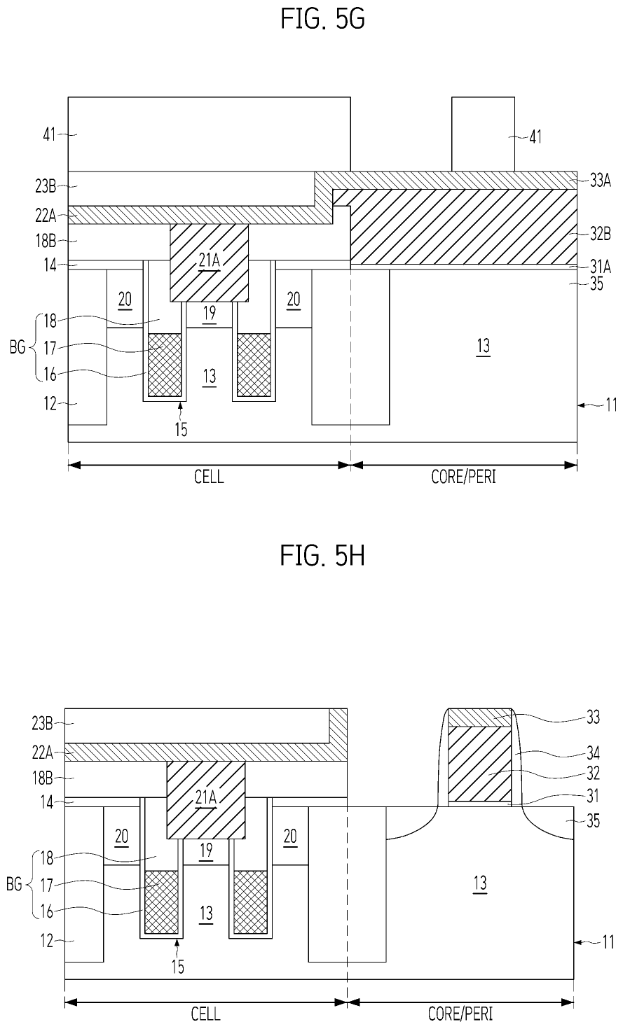

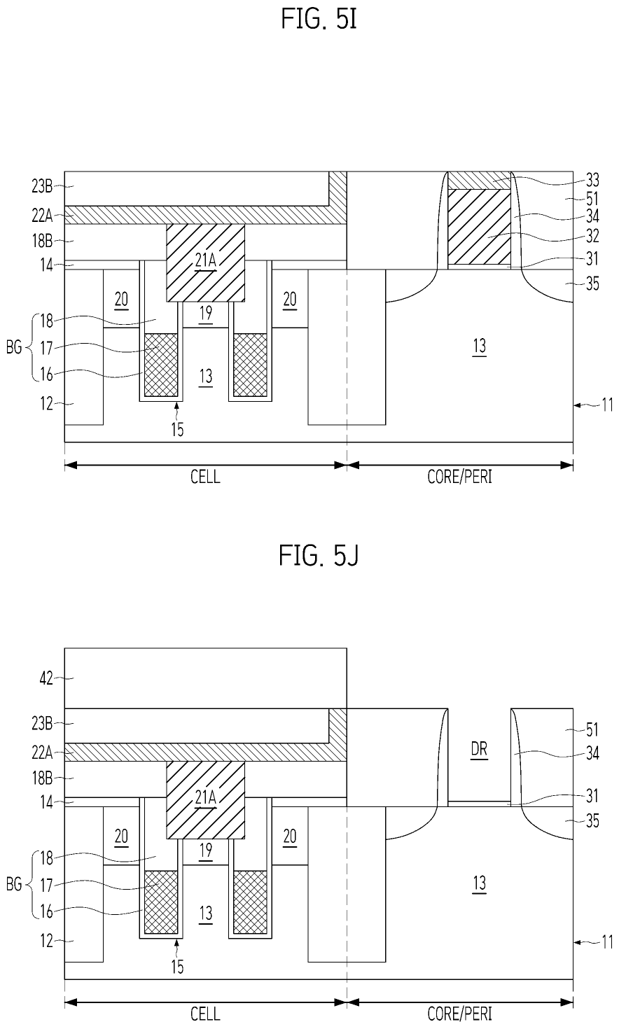

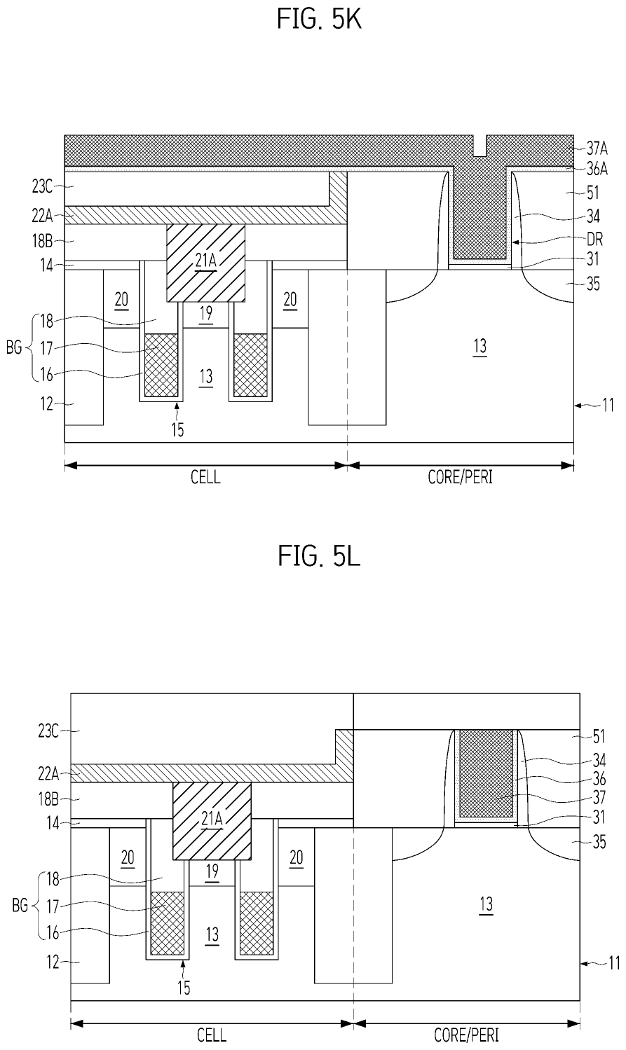

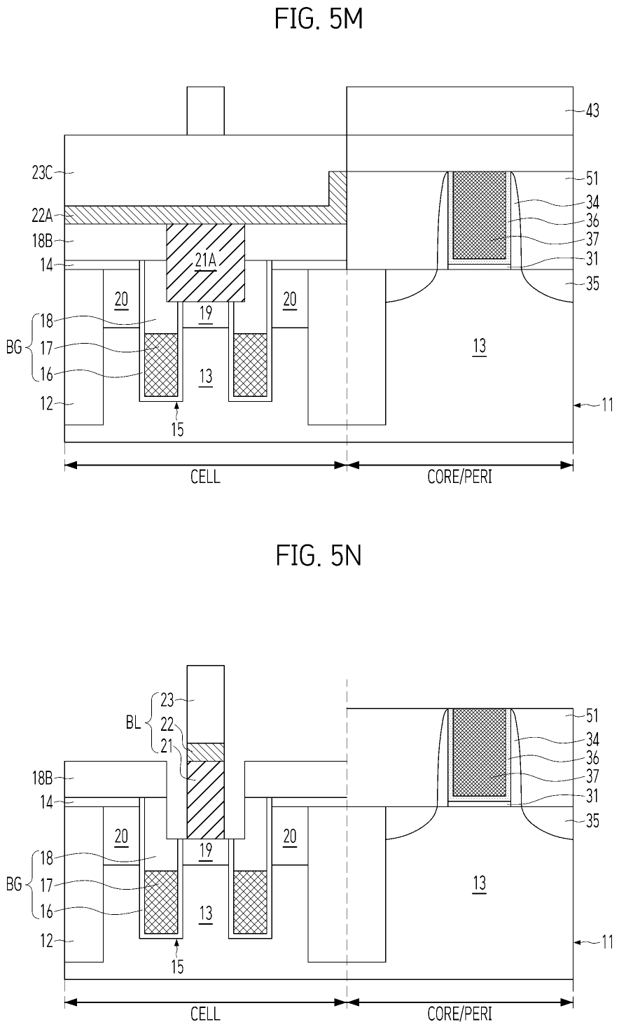

FIGS. 5A to 5N are cross-sectional views illustrating a method for fabricating a semiconductor device in accordance with another embodiment of the present invention.

Referring to FIG. 5A, the semiconductor device may provide a substrate 11 including a cell region CELL and core/peripheral regions CORE/PERI.

The cell region CELL may include a word line, a bit line, a capacitor, and the like. The cell region CELL may be a memory cell region for storing data and may be driven by selecting a word line and a bit line. The core/peripheral regions CORE/PERI may include a core region and a peripheral circuit region.

Although this embodiment of the present invention illustrates one gate structure that is formed in the core/peripheral region for the sake of convenience in description, the concept and scope of the present invention are not limited thereto, and an appropriate gate structure selected for one or more of the gate structures illustrated in FIGS. 1A to 1C and FIGS. 2A to 2C may be applied according to the needs or each region. According to this embodiment of the present invention, each of the core region or the peripheral region illustrated in FIG. 4 may be formed separately, and a gate structure suitable for each region may be formed. As illustrated in FIG. 3, each of the core region and the peripheral region according to this embodiment of the present invention may be divided into an NMOS region and a PMOS region, and into a high voltage transistor region and a low voltage transistor region, and a gate structure suitable for each region may be formed. In particular, according to one embodiment of the present invention, the gate structures of the core/peripheral regions may be formed through different processes to have structures that are different according to what is required. For example, when the gate structure of the core region is formed, the peripheral region may be covered by a mask pattern, and when the gate structure of the peripheral region is formed, the core region may be covered by the mask pattern.

In FIG. 5A, the substrate 11 may include an isolation layer 12 and an active region 13 that is defined by the isolation layer 12. The active regions 13 may be spaced apart at regular intervals by the isolation layer 12. The isolation layer 12 may separate the cell region CELL and the core/peripheral region CORE/PERI from each other.

The substrate 11 may be a material appropriate for semiconductor processing. The substrate 11 may include a semiconductor substrate. The substrate 11 may be formed of a silicon-containing material. The substrate 11 may include for example one or more of silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 11 may also include another semiconductor material, such as for example germanium. The substrate 11 may include a III/V-group semiconductor substrate, for example, a compound semiconductor substrate, such as GaAs. The substrate 11 may include a Silicon-On-Insulator (SOI) substrate.

The isolation layer 12 may be formed by a shallow trench isolation (STI) process. The STI process may be performed as follows. The substrate 11 may be etched to form an isolation trench. The isolation trench may be filled with a dielectric material, and as a result, an isolation layer 12 may be formed. The isolation layer 12 may include silicon oxide, silicon nitride, or a combination thereof. A Chemical Vapor Deposition (CVD) or other deposition processes may be used to fill the isolation trench with a dielectric material. A planarization process such as Chemical Mechanical Polishing (CMP) may additionally be used.

Subsequently, a buried gate structure BG may be formed in the substrate 11 of the cell region CELL. The buried gate structure BG may include a gate trench 15, a gate dielectric layer 16 covering the bottom surface and sidewalls of the gate trench 15, a buried gate electrode 17 partially filling the gate trench 15 over the gate dielectric layer 16, and a gate capping layer 18 formed over the buried gate electrode 17.

The buried gate structure BG may be formed as follows.

First, the gate trench 15 may be formed in the substrate 11 of the cell region CELL. The gate trench 15 may have a line shape crossing the active regions 13 and the isolation layer 12. The gate trench 15 may be formed by forming a mask pattern over the substrate 11 and performing an etching process using the mask pattern as an etching mask. In order to form the gate trench 15, a hard mask layer 14 may be used as an etch barrier. The hard mask layer 14 may have a shaped that is patterned by a mask pattern. The hard mask layer 14 may cover the profile of the substrate of the core/peripheral regions CORE/PERI. The hard mask layer 14 may include silicon oxide. The hard mask layer 14 may include tetra ethyl ortho silicate (TEOS). The bottom surface of the gate trench 15 may be disposed at a higher level than the bottom surface of the isolation layer 12.

The active region 13 below the gate trench 15 may protrude by recessing a portion of the isolation layer 12 of the cell region CELL. Accordingly, a fin region may be formed below the gate trench 15. The fin region may be part of a channel region.

Subsequently, the gate dielectric layer 16 may be formed on the bottom surface and sidewalls of the gate trench 15. Before the gate dielectric layer 16 is formed, etching damage on the surface of the gate trench 15 may be addressed. For example, after a sacrificial oxide is formed by a thermal oxidation treatment, the sacrificial oxide may be removed.

The gate dielectric layer 16 may be formed by a thermal oxidation process. For example, the gate dielectric layer 16 may be formed by oxidizing the bottom surface and sidewalls of the gate trench 15.

According to another embodiment of the present invention, the gate dielectric layer 16 may be formed by a deposition method, such as chemical vapor deposition (CVD) or atomic layer deposition (ALD). The gate dielectric layer 16 may include one or more of a high-k material, an oxide, a nitride, an oxynitride, or a combination thereof. The high-k material may include a hafnium oxide material. The hafnium-containing material may include one or more of hafnium oxide, hafnium silicon oxide, hafnium silicon oxynitride, or a combination thereof. According to another embodiment of the present invention, the high-k material may include one or more of lanthanum oxide, lanthanum aluminum oxide, zirconium oxide, zirconium silicon oxide, zirconium silicon oxynitride, aluminum oxide, or a combination thereof.

According to another embodiment of the present invention, the gate dielectric layer 16 may be formed by depositing a liner polysilicon layer and then radical-oxidizing the liner polysilicon layer.

According to yet another embodiment of the present invention, the gate dielectric layer 16 may be formed by forming a liner silicon nitride layer and then radical-oxidizing the liner silicon nitride layer.

Subsequently, the buried gate electrode 17 may be formed over the gate dielectric layer 16. The buried gate electrode 17 may be formed by forming a conductive layer to fill the gate trench 15 and then performing a recessing process. The recessing process may be performed as an etch-back process or may be performed by sequentially performing a chemical mechanical polishing (CMP) process and an etch-back process. The buried gate electrode 17 may have a recessed shape that partially fills the gate trench 15. In other words, the top surface of the buried gate electrode 17 may be disposed at a lower level than the top surface of the active region 13. The buried gate electrode 17 may include a metal, a metal nitride, or a combination thereof. For example, the buried gate electrode 17 may be formed from one or more of titanium nitride (TiN), tungsten (W), or a titanium nitride/tungsten (TiN/W) stack. The titanium nitride/tungsten (TiN/W) stack may have a structure in which titanium nitride is conformally formed and then the gate trench 15 is partially filled with tungsten. As the buried gate electrode 17, titanium nitride may be used alone, and this may be referred to as a buried gate electrode 17 of a ‘TiN Only’ structure. As the buried gate electrode 17, a double gate structure of a titanium nitride/tungsten (TiN/W) stack and a polysilicon layer may be used.

Subsequently, capping layers 18 and 18A may be formed over the profile of the substrate including the buried gate electrode 17. The capping layers 18 and 18A may include a dielectric material. The capping layers 18 and 18A may include silicon nitride. According to another embodiment of the present invention, the capping layers 18 and 18A may include silicon oxide. According to yet another embodiment of the present invention, the capping layers 18 and 18A may have a Nitride-Oxide-Nitride (NON) structure.

The capping layers 18 and 18A may include a gate capping layer 18 gap-filling the gate trench 15 over the buried gate electrode 17, and a protective capping layer 18A covering the upper portion of the hard mask layer 14. A buried gate structure BG may be formed by the gate dielectric layer 16, the buried gate electrode 17 and the gate capping layer 18. The buried gate structure BG may be referred to as a ‘word line WL’.

The top surface of the protective capping layer 18A may be disposed at a higher level than the top surface of the hard mask layer 14. The protective capping layer 18A may cover both of the hard mask layer 14 and the buried gate structure BG.

Subsequently, a bit line contact hole BH may be formed in the cell region CELL. The bit line contact hole BH may be disposed between the neighboring buried gate structures BG. A contact mask for etching the protective capping layer 18A and the hard mask layer 14 may be applied to form the bit line contact hole BH. A portion of the substrate 11 may be exposed by the bit line contact hole BH. The bit line contact hole BH may have a diameter that is controlled to a constant line width. The bit line contact hole BH may have a shape that exposes a part of the active region 13. The bit line contact hole BH may have a larger diameter than the width of the minor axis of the active region 13. Accordingly, in an etching process for forming the bit line contact hole BH, portions of the isolation layer 12 and the active region 13 may be etched. In other words, the isolation layer 12 and the active region 13 below the bit line contact hole BH may be recessed to a certain depth. Accordingly, the bottom portion of the bit line contact hole BH may extend into the substrate 11.

Subsequently, a preliminary bit line contact 21A may be formed to gap-fill the bit line contact hole BH. The preliminary bit line contact 21A may be formed by a series of processes of forming a plug conductive layer over the bit line contact hole BH and the protective capping layer 18A, and etching the plug conductive layer to remain only in the bit line contact hole BH. The preliminary bit line contact 21A may include a material having an etch selectivity with respect to the protective capping layer 18A. For example, the preliminary bit line contact 21A may include polysilicon. According to another embodiment of the present invention, the preliminary bit line contact 21A may include polysilicon that is doped with an impurity.

Referring to FIG. 5B, the protective capping layer 18A (see FIG. 5A) of the core/peripheral region CORE/PERI may be etched. Accordingly, the protective capping layer 18B may remain only in the cell region CELL. In the core/peripheral regions CORE/PERI, the substrate 11 may be exposed.

Subsequently, a preliminary gate dielectric layer 31A may be formed over the substrate 11 of the core/peripheral regions CORE/PERI. The preliminary gate dielectric layer 31A may form a peripheral gate dielectric layer of the peripheral gate structure through a subsequent process. The preliminary gate dielectric layer 31A may include a dielectric material. For example, the preliminary gate dielectric layer 31A may include silicon oxide. The preliminary gate dielectric layer 31A may be formed through a deposition process or an oxidation process. According to this embodiment of the present invention, the preliminary gate dielectric layer 31A may be formed through an oxidation process. Therefore, the preliminary gate dielectric layer 31A may be selectively formed only over the upper portion of the active region 13 of the core/peripheral region CORE/PERI.

Referring to FIG. 5C, a first dummy gate conductive layer 32A may be formed over the entire structure including the preliminary gate dielectric layer 31A of the core/peripheral region CORE/PERI. The first dummy gate conductive layer 32A may include the same material as that of the preliminary bit line contact 21A. For example, the first dummy gate conductive layer 32A may include polysilicon.

Referring to FIG. 5D, a cell open mask 40 may be formed over the first dummy gate conductive layer 32A of the core/peripheral regions CORE/PERI. The cell open mask 40 may be a mask for opening the cell region CELL, and may cover the core/peripheral regions CORE/PERI. The cell open mask 40 may include a photoresist.

Subsequently, the first dummy gate conductive layer 32A (see FIG. 5C) of the cell region CELL may be etched. Therefore, in the cell region CELL, the protective capping layer 18B and the preliminary bit line contact 21A may be exposed, and the first dummy gate conductive layer 32A may remain only in the core/peripheral regions CORE/PERI.

Subsequently, the cell open mask 40 may be removed.

Referring to FIG. 5E, the conductive layers 22A and 33B and the hard mask layer 34A may be sequentially formed over the protective capping layer 18B and the preliminary bit line contact 21A of the cell region CELL and the first dummy gate conductive layer 32B of the core/peripheral region CORE/PERI.

The conductive layers 22A and 33A may include a metal-containing material. The conductive layers 22A and 33A may include one or more of a metal, a metal nitride, a metal silicide, or a combination thereof. According to this embodiment of the present invention, the conductive layers 22A and 33A may include tungsten (W). According to another embodiment of the present invention, the conductive layers 22A and 33A may include a stack (TiN/W) of titanium nitride and tungsten. Herein, the titanium nitride may serve as a barrier. According to another embodiment of the present invention, the conductive layers 22A and 33A may include a stacked structure of Ti/WN/WSiN/W. The conductive layers 22A and 33A may be applied to form a bit line of the cell region CELL and a dummy gate of the core/peripheral region CORE/PERI in a subsequent process. Hereinafter, the conductive layer 22A of the cell region CELL will be referred to as a ‘bit line conductive layer 22A’. The conductive layer 33A of the core/peripheral region CORE/PERI will be referred to as a ‘second dummy gate conductive layer 33A’.

The hard mask layer 34A may include a material having an etch selectivity with respect to the bit line conductive layer 22A and the second dummy gate conductive layer 33A. The hard mask layer 34A may include a dielectric material. For example, the hard mask layer 34A may include silicon nitride.

Referring to FIG. 5F, the hard mask layer 34A (see FIG. 5E) of the core/peripheral regions CORE/PERI may be removed. The hard mask layer 34A (see FIG. 5E) may be etched targeting to expose the second dummy gate conductive layer 33A of the core/peripheral regions CORE/PERI. The hard mask layer 34A (see FIG. 5E) may be etched by a chemical mechanical polishing process.

Therefore, the bit line hard mask layer 23B may remain only in the cell region CELL.

Referring to FIG. 5G, a first mask pattern 41 may be formed. The first mask pattern 41 may be patterned to cover the entire cell region CELL and define a gate region of the core/peripheral region CORE/PERI at the same time. The first mask pattern 41 may include a photoresist.

Referring to FIG. 5H, the second dummy gate conductive layer 33A (see FIG. 5G), the first dummy gate conductive layer 32B (see FIG. 5G) and the preliminary gate dielectric layer 31A (see FIG. 5G) of the core/peripheral regions CORE/PERI may be sequentially etched using the first mask pattern 41 (see FIG. 5G) as an etch barrier. Since the cell region CELL is entirely covered by the first mask pattern 41 (see FIG. 5G), it may not be etched.

Therefore, a dummy gate structure in which a peripheral gate dielectric layer 31, a first dummy gate 32, and a second dummy gate 33 are stacked may be formed over the substrate 11 of the core/peripheral regions CORE/PERI.

Subsequently, the peripheral gate spacer 34 may be formed on both sidewalls of the dummy gate structure. The peripheral gate spacer 34 may include a dielectric material. For example, the peripheral gate spacer 34 may include silicon nitride, but the concept and scope of the present invention are not limited thereto.

Subsequently, a peripheral junction region 35 may be formed in the substrate 11 on both sides of the dummy gate structure. The peripheral junction region 35 may be formed by doping an impurity onto the substrate 11 that is exposed by the patterning of the dummy gate structure. The peripheral junction region 35 may be referred to as a ‘peripheral source/drain region 35’.

As described above, reliability of the RMG structure to be formed by a subsequent process may be secured by performing the peripheral junction region 35 process requiring a high-temperature heat treatment before the RMG structure is formed.

Referring to FIG. 5I, an inter-layer dielectric layer 51 may be formed over the substrate 11 of the core/peripheral regions CORE/PERI. The inter-layer dielectric layer 51 may fill the gap between the dummy gate structures. The inter-layer dielectric layer 51 may include a dielectric material. For example, the inter-layer dielectric layer 51 may include silicon oxide, but the concept and scope of the present invention are not limited thereto.

Referring to FIG. 5J, a peripheral open mask 42 may be formed. The peripheral open mask 42 may be formed over the bit line hard mask layer 23B of the cell region CELL. The peripheral open mask 42 may be a mask for opening the core/peripheral regions CORE/PERI, and may cover the cell region CELL. The peripheral open mask 42 may include a photoresist.

Subsequently, the first and second dummy gates 32 and 33 (see FIG. 5I) may be removed. Thus, a dummy recess DR may be formed between the facing dummy gate spacers 34.

Subsequently, the peripheral open mask 42 may be removed.

Referring to FIG. 5K, a preliminary high-k layer 36A may be formed to cover the inner sidewall and bottom surface of the dummy recess DR. For example, the preliminary high-k layer 36A may include hafnium oxide. The hafnium-containing material may include one or more of hafnium oxide, hafnium silicon oxide, hafnium silicon oxynitride, or a combination thereof. According to other embodiments of the present invention, the high-k material may include one or more of lanthanum oxide, lanthanum aluminum oxide, zirconium oxide, zirconium silicon oxide, zirconium silicon oxynitride, aluminum oxide, or a combination thereof.

Subsequently, a preliminary gate conductive layer 37A may be formed over the preliminary high-k layer 36A to gap-fill the dummy recess DR. The preliminary gate conductive layer 37A may include a metal material. For example, the preliminary gate conductive layer 37A may include tungsten (W), but the concept and scope of the present invention are not limited thereto.

Referring to FIG. 5L, an RMG structure in which a peripheral gate dielectric layer 31, a peripheral high-k layer 36, and a peripheral gate electrode 37 are stacked may be formed. To this end, the preliminary high-k layer 36A (see FIG. 5K) and the preliminary gate conductive layer 37A (see FIG. 5K) of the remaining region except for the dummy recess DR (see FIG. 5K) may be etched. For example, the preliminary high-k layer 36A (see FIG. 5K) and the preliminary gate conductive layer 37A (see FIG. 5K) may be etched through a Chemical Mechanical Polishing (CMP) process, but the concept and scope of the present invention are not limited thereto.

Subsequently, the thickness of the bit line hard mask layer 23C of the cell region CELL may be increased. To this end, the same material as that of the bit line hard mask layer 23B (see FIG. 5K) may be additionally deposited over the bit line hard mask layer 23B once the preliminary high-k layer 36A and the preliminary gate conductive layer 37A have been etched through (see FIG. 5K).

Referring to FIG. 5M, a second mask pattern 43 may be formed. The second mask pattern 43 may be patterned to cover both of the core/peripheral regions CORE/PERI and define the bit line region of the cell region CELL at the same time. The second mask pattern 43 may include a photoresist.

Referring to FIG. 5N, the bit line hard mask layer 23C (see FIG. 5M), the bit line conductive layer 22A (see FIG. 5M) and the preliminary bit line contact 21A (see FIG. 5M) of the cell region CELL may be sequentially etched by using the second mask pattern 43 (see FIG. 5M) as an etch barrier. Since the core/peripheral regions CORE/PERI are entirely covered by the second mask pattern 43 (see FIG. 5M), it may remain without being damaged.

Accordingly, a bit line structure BL in which the bit line contact 21, the bit line 22, and the bit line hard mask 23 are stacked may be formed in the cell region CELL.

Subsequently, impurity regions 19 and 20 may be formed in the substrate 11 on both sides of the buried gate structure BG. The impurity regions 19 and 20 may be formed by a doping process, such as implantation. The impurity regions 19 and 20 may be referred to as ‘cell source/drain regions’. The impurity region 19 between the neighboring buried gate structures BG may be regions to which bit line contact plugs are to be coupled. The impurity region 20 outside the buried gate structure BG may be a region to which a storage node contact plug is to be coupled. According to this embodiment of the present invention, a process of forming the impurity regions 19 and may be performed after the bit line structure BL is formed, but the present embodiment is not limited thereto. According to another embodiment of the present invention, the impurity regions 19 and 20 may be formed after the buried gate structure BG is formed. According to another embodiment of the present invention, the impurity regions 19 and 20 may be formed after the gate trench 15 is formed.

According to one embodiment of the present invention, there is an effect of securing improved semiconductor reliability and improving performance by applying a gate structure that is optimized for a core region and a peripheral region.

While the present invention has been described with respect to the specific embodiments, it will be apparent to those skilled in the art that various changes and modifications may be made without departing from the spirit and scope of the invention.

What is claimed is:

1. A semiconductor device, comprising:
a substrate including a core region and a peripheral region;
a first conductive pattern including a first stacked structure comprising a first gate dielectric layer and a first gate electrode over the substrate of the core region, and including a first high-k layer interposed at an interface between the first gate dielectric layer and the first gate electrode; and
a second conductive pattern including a second stacked structure comprising a second gate dielectric layer and a second gate electrode over the substrate of the peripheral region, and including a second high-k layer interposed at an interface between the second gate dielectric layer and the second gate electrode and covering sidewalls of the second gate electrode.

2. The semiconductor device of claim 1, wherein the first conductive pattern further includes
a first dipole layer interposed at an interface between the first high-k layer and the first gate electrode.

3. The semiconductor device of claim 1, wherein the first conductive pattern further includes
a dipole layer suitable for covering an interface between the first high-k layer and the first gate electrode and covering the sidewalls of the first gate electrode.

4. The semiconductor device of claim 1, wherein the second conductive pattern further includes
a second dipole layer interposed at an interface between the second high-k layer and the second gate dielectric layer.

5. The semiconductor device of claim 1, wherein the second conductive pattern further includes
a second dipole layer interposed between the second high-k layer and the second gate electrode to cover a bottom surface and the sidewalls of the gate electrode.

6. A semiconductor device, comprising:
a substrate including a core region and a peripheral region, each region including an NMOS region and a PMOS region;
a first gate structure formed over the substrate of the NMOS regions of the core region and including a first stacked structure comprising a first gate dielectric layer, a first high-k layer, and a first gate electrode;
a second gate structure formed over the substrate of the NMOS regions of the peripheral region and including a second stacked structure comprising a second gate dielectric layer, a second high-k layer, and a second gate electrode;
a third gate structure formed over the substrate of the PMOS regions of the core region and including a third stacked structure comprising a third gate dielectric layer, a first dipole layer, a third high-k layer, and a third gate electrode; and
a fourth gate structure formed over the substrate of the PMOS regions of and the peripheral region and including a fourth stacked structure comprising a fourth gate dielectric layer, a second dipole layer, a fourth high-k layer, and a fourth gate electrode.

7. The semiconductor device of claim 6, wherein in the first gate structure, the first gate dielectric layer and the first high-k layer are of a bar-shape.

8. The semiconductor device of claim 6, wherein in the second gate structure,
the second gate dielectric layer is of a bar shape;
the second high-k layer is U-shaped, and
a bottom surface and sidewalls of the second gate electrode are covered by the second high-k layer.

9. The semiconductor device of claim 6, wherein the first gate structure further includes
a third dipole layer between the first high-k layer and first the gate electrode.

10. The semiconductor device of claim 6, wherein the second gate structure further includes a fourth dipole layer between the second high-k layer and second the gate electrode.

11. The semiconductor device of claim 9, wherein in the first gate structure,
the first gate dielectric layer and the first high-k layer are of a bar-shape,
the third dipole layer is U-shaped, and
a bottom surface and sidewalls of the first gate electrode are covered by the third dipole layer.

12. The semiconductor device of claim 10, wherein in the second gate structure,
the second gate dielectric layer is of a bar shape,
the second high-k layer and the fourth dipole layer are U-shaped,
the second high-k layer covers an outer sidewall of the fourth dipole layer, and
a bottom surface and sidewalls of the second gate electrode are covered by the fourth dipole layer.

13. The semiconductor device of claim 6, wherein in the third gate structure,
the third gate dielectric layer, the third dipole layer, and the third high-k layer are of a bar-shape.

14. The semiconductor device of claim 6, wherein in the fourth gate structure,
the fourth gate dielectric layer and the fourth dipole layer are of a bar-shape,
the fourth high-k layer is U-shaped, and
a bottom surface and sidewalls of the fourth gate electrode are covered by the fourth high-k layer.

15. The semiconductor device of claim 6, wherein each of the core region and the peripheral region includes a low voltage transistor region and a high voltage transistor region, and
a gate structure of the low voltage transistor region has a line width that is smaller than a line width of the gate structure of the high voltage transistor region.

16. The semiconductor device of claim 6, wherein the first to fourth gate structures are replacement metal gate (RMG) structures.

17. The semiconductor device of claim 6, wherein each of the first gate structure to the fourth gate structure further includes gate spacers on sidewalls thereof.
